(19) United States
(12) Patent Application Publication
(10) Pub. No.: US 2024/0389362 A1
(43) Pub. Date: Nov. 21, 2024

(54) SEMICONDUCTOR DEVICE INCLUDING MEMORY CELLS STACKED IN VERTICAL DIRECTION

(71) Applicant: SK hynix Inc., Icheon-si (KR)

(72) Inventor: Si Jung YOO, Icheon-si (KR)

(21) Appl. No.: 18/501,872

(22) Filed: Nov. 3, 2023

(30) Foreign Application Priority Data
May 16, 2023 (KR) 10-2023-0062939

(51) Int. Cl. H10B 63/00; H10B 61/00

(52) U.S. Cl. CPC H10B 63/84; H10B 61/00

(57) ABSTRACT

A semiconductor device includes: first to fourth word lines alternately arranged with first to third bit lines in a vertical direction; first to sixth memory cells disposed between the first word line and the first bit line, between the first bit line and the second word line, between the second word line and the second bit line, between the second bit line and the third word line, between the third word line and the third bit line, and between the third bit line and the fourth word line, respectively; first and second word line contacts respectively connecting the first and second word lines to the substrate; third and fourth word line contacts respectively connecting the third and fourth word lines to the first and second word lines; and first to third bit line contacts respectively connecting the first to third bit lines to the substrate.

### CROSS-REFERENCE TO RELATED APPLICATION

This application claims priority under 35 U.S.C. § 119 to Korean Patent Application No. 10-2023-0062939 filed on May 16, 2023, which is incorporated herein by reference in its entirety.

### BACKGROUND

### 1. Technical Field

This patent document relates to a semiconductor technology, and more particularly, to a semiconductor device including a plurality of memory cells that are stacked in a vertical direction.

### 2. Related Art

Recently, as electronic appliances trend toward miniaturization, low power consumption, high performance, multi-functionality, and so on, semiconductor devices capable of storing information in various electronic appliances such as a computer, a portable communication device, and so on have been demanded in the art, and research has been conducted for the semiconductor devices. Such semiconductor devices include semiconductor devices which can store data using a characteristic that they are switched between different resistant states according to an applied voltage or current, for example, an RRAM (resistive random access memory), a PRAM (phase change random access memory), an FRAM (ferroelectric random access memory), an MRAM (magnetic random access memory), an E-fuse, etc.

### SUMMARY

In an embodiment, a semiconductor device may include: a substrate; first to fourth word lines extending in a first direction that is parallel to a top surface of the substrate, and sequentially stacked over the substrate in a vertical direction perpendicular to the top surface of the substrate; first to third bit lines extending in a second direction that is parallel to the top surface of the substrate and crosses the first direction, and disposed between the first word line and the second word line, between the second word line and the third word line, and between the third word line and the fourth word line, respectively, in the vertical direction; first to sixth memory cells disposed in an intersection region between the first word line and the first bit line, an intersection region between the first bit line and the second word line, an intersection region between the second word line and the second bit line, an intersection region between the second bit line and the third word line, an intersection region between the third word line and the third bit line, and an intersection region between the third bit line and the fourth word line, respectively; first and second word line contacts respectively connecting the first and second word lines to the substrate, and third and fourth word line contacts respectively connecting the third and fourth word lines to the first and second word lines; and first to third bit line contacts respectively connecting the first to third bit lines to the substrate, wherein, in a plan view, a first word line contact region where the first and third word line contacts are disposed, a second word line contact region where the second and fourth word line contacts are disposed, a first bit line contact region where the first bit line contact is disposed, a second bit line contact region where the second bit line contact is disposed, and a third bit line contact region where the third bit line contact is disposed are located at different positions.

In another embodiment, a semiconductor device may include: a substrate including a plurality of tiles arranged in a first direction and a second direction, the first and the second direction being parallel to a top surface of the substrate and crossing each other, the substrate further including first and second word line contact regions and first to third bit line contact regions that are arranged in different tiles; first to fourth word lines extending in the first direction and sequentially stacked over the substrate in a vertical direction perpendicular to the top surface of the substrate; first, second, and third bit lines extending in the second direction, and disposed between the first word line and the second word line, between the second word line and the third word line, and the third word line and the fourth word line, respectively, in the vertical direction; first to sixth memory cells disposed in an intersection region between the first word line and the first bit line, an intersection region between the first bit line and the second word line, an intersection region between the second word line and the second bit line, an intersection region between the second bit line and the third word line, an intersection region between the third word line and the third bit line, and an intersection region between the third bit line and the fourth word line, respectively; first and third word line contacts connecting the first and third word lines to the first word line contact region of the substrate; second and fourth word line contacts connecting the second and fourth word lines to the second word line contact region of the substrate; and first to third bit line contacts respectively connecting the first to third bit lines to the first to third bit line contact regions of the substrate.

### BRIEF DESCRIPTION OF THE DRAWINGS

FIG. 1A is a plan view illustrating a semiconductor device according to an embodiment of the present disclosure.

FIG. 1B is a cross-sectional view taken along a first direction of FIG. 1A.

FIG. 1C is a cross-sectional view taken along a second direction of FIG. 1A.

FIG. 1D is a cross-sectional view illustrating an example of a memory cell MC of FIGS. 1A to 1C.

FIG. 2A is a plan view illustrating a semiconductor device according to another embodiment of the present disclosure.

FIG. 2B is a cross-sectional view taken along a first direction of FIG. 2A.

FIG. 2C is a cross-sectional view taken along a second direction of FIG. 2A.

FIG. 3A is a plan view illustrating an enlarged portion P1 of FIG. 2A.

FIG. 3B is a cross-sectional view taken along a first direction of FIG. 3A.

FIG. 3C is a cross-sectional view taken along a second direction of FIG. 3A.

### DETAILED DESCRIPTION

Hereinafter, various embodiments of the disclosure will be described in detail with reference to the accompanying drawings.

The drawings are not necessarily drawn to scale. In some instances, proportions of at least some structures in the drawings may have been exaggerated in order to clearly illustrate certain features of the described embodiments. In presenting a specific example in a drawing or description having two or more layers in a multi-layer structure, the relative positioning relationship of such layers or the sequence of arranging the layers as shown reflects a particular implementation for the described or illustrated example and a different relative positioning relationship or sequence of arranging the layers may be possible. In addition, a described or illustrated example of a multi-layer structure might not reflect all layers present in that particular multilayer structure (e.g., one or more additional layers may be present between two illustrated layers). As a specific example, when a first layer in a described or illustrated multi-layer structure is referred to as being “on” or “over” a second layer or “on” or “over” a substrate, the first layer may be directly formed on the second layer or the substrate but may also represent a structure where one or more other intermediate layers may exist between the first layer and the second layer or the substrate.

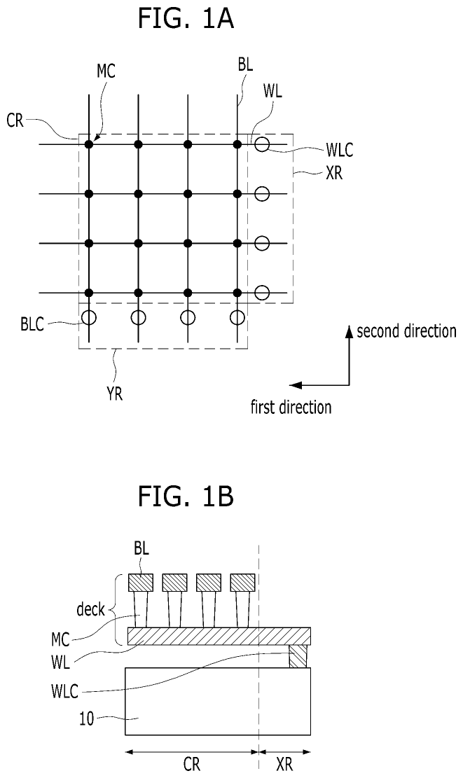

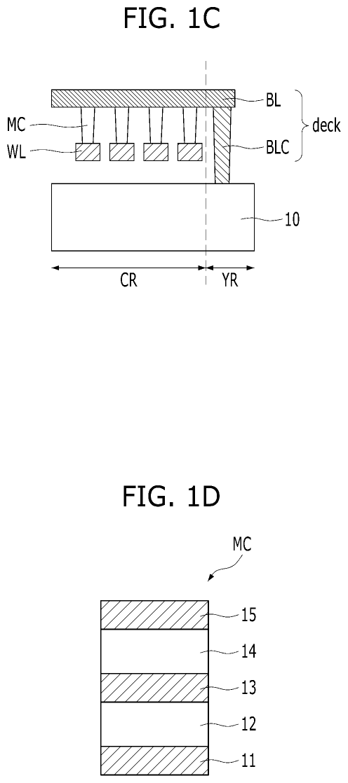

FIG. 1A is a plan view illustrating a semiconductor device according to an embodiment of the present disclosure. FIG. 1B is a cross-sectional view taken along a first direction of FIG. 1A, and FIG. 1C is a cross-sectional view taken along a second direction of FIG. 1A. Referring to FIGS. 1A to 1C, the semiconductor device of the present embodiment may include a substrate 10, a plurality of word lines WL formed over the substrate 10 in a third direction and extending in the first direction, a plurality of word line contacts WLC disposed between the substrate 10 and the word lines WL in the third direction and respectively connecting the word lines WL to the substrate 10, a plurality of bit lines BL formed over the word lines WL in the third direction and extending in the second direction crossing the first direction, a plurality of bit line contacts BLC disposed between the substrate 10 and the bit lines BL in the third direction and respectively connecting the bit lines BL to the substrate 10, and a plurality of memory cells MC disposed between the word lines WL and the bit lines BL in the third direction and respectively disposed at intersections of the word lines WL and the bit lines BL. Here, the first direction and the second direction may be substantially parallel to an upper surface of the substrate 10, the third direction may be substantially perpendicular to the upper surface of the substrate 10. The third direction substantially perpendicular to the upper surface of the substrate 10 will be also referred to as a vertical direction.

The substrate 10 may include a semiconductor material such as silicon. In addition, a desired lower structure (not shown) may be formed in the substrate 10. For example, integrated circuits for driving the word lines WL and the bit lines BL may be formed in the substrate 10.

The plurality of word lines WL may be arranged parallel to each other in the second direction and positioned at substantially the same vertical level. The plurality of bit lines BL may be arranged parallel to each other in the first direction and positioned at substantially the same vertical level. The plurality of memory cells MC may be arranged in a matrix form along the first and second directions and positioned at the intersections of the plurality of word lines WL and the plurality of bit lines BL. In a plan view, a region where the plurality of word lines WL and the plurality of bit lines BL cross each other, that is, a region where the plurality of memory cells MC are arranged, will be referred to as a cell array region CR.

The plurality of word line contacts WLC may be connected to the plurality of word lines WL, respectively. The word line contacts WLC may serve to connect the word lines WL to the substrate 10, in particular, to a word line driving circuit formed in the substrate 10. A word line contact WLC may have a pillar shape. Although a single pillar forms the word line contact WLC in this figure, embodiments of the present disclosure are not limited thereto. Two or more pillars may be stacked to form the word line contact WLC.

The plurality of bit line contacts BLC may be connected to the plurality of bit lines BL, respectively. The bit line contacts BLC may serve to connect the bit lines BL to the substrate 10, in particular, to a bit line driving circuit formed in the substrate 10. A bit line contact BLC may have a pillar shape. Although a single pillar forms the bit line contact BLC in this figure, embodiments of the present disclosure are not limited thereto. Two or more pillars may be stacked to form the bit line contact BLC.

In a plan view, a region in which the plurality of word line contacts WLC are arranged will be referred to as a word line contact region XR. Since the plurality of word line contacts WLC are arranged in the second direction, the word line contact region XR may either have a bar shape with a greater length in the second direction than in the first direction, or a shape similar thereto. The word line contact region XR may be located on one side, e.g., the right side, of the cell array region CR in the first direction with respect to the orientation of FIG. 1A. All or part of the word line driving circuit may overlap the word line contact region XR in a plan view.

In addition, in a plan view, a region in which the plurality of bit line contacts BLC are arranged will be referred to as a bit line contact region YR. Since the plurality of bit line contacts BLC are arranged in the first direction, the bit line contact region YR may either have a bar shape with a greater length in the first direction than in the second direction, or a shape similar thereto. The bit line contact region YR may be located on one side, e.g., the lower side, of the cell array region CR in the second direction with respect to the orientation of FIG. 1A. All or part of the bit line driving circuit may overlap the bit line contact region YR in a plan view.

Each of the word line WL, the word line contact WLC, the bit line BL, and the bit line contact BLC may independently include one or more of various conductive materials. For example, each of the word line WL, the word line contact WLC, the bit line BL, and the bit line contact BLC may independently include a metal such as platinum (Pt), tungsten (W), aluminum (Al), copper (Cu), or tantalum (Ta), a metal nitride such as titanium nitride (TiN) or tantalum nitride (TaN), or a combination thereof, and may have a single layer structure or a multilayer structure.

The memory cell MC may have a pillar shape, overlapping the intersection of the word line WL and the bit line BL. The memory cell MC may store data, and may have a single layer structure or a multilayer structure. For example, the memory cell MC may include a variable resistance element that stores different data by switching between different resistance states according to an applied voltage or current. This will be described with reference to FIG. 1D.

FIG. 1D is a cross-sectional view illustrating an example of the memory cell MC of FIGS. 1A to 1C.

Referring to FIG. 1D, the memory cell MC may have a multilayer structure including a lower electrode layer 11, a selector layer 12, an intermediate electrode layer 13, a variable resistance layer 14, and an upper electrode layer 15.

The lower electrode layer 11 and the upper electrode layer 15 may be positioned at the bottom and the top of the memory cell MC, respectively, and may transfer a voltage or current necessary for the operation of the memory cell MC. The intermediate electrode layer 13 may electrically connect the selector layer 12 and the variable resistance layer 14 while physically separating them from each other. The lower electrode layer 11, the intermediate electrode layer 13, or the upper electrode layer 15 may include one or more of various conductive materials, for example, a metal such as platinum (Pt), tungsten (W), aluminum (Al), copper (Cu), or tantalum (Ta), a metal nitride such as titanium nitride (TiN) or tantalum nitride (TaN), or a combination thereof. Alternatively, the lower electrode layer 11, the intermediate electrode layer 13, or the upper electrode layer 15 may include a carbon electrode.

The selector layer 12 may function to prevent current leakage that may occur between memory cells MC sharing a word line WL or a bit line BL. To this end, the selector layer 12 may have a threshold switching characteristic. That is, when the applied voltage is less than a threshold voltage, almost no current flows through the selector layer 12, but when the applied voltage exceeds the threshold voltage, the current flowing through the selector layer 12 rapidly increases. The selector layer 12 may be implemented in a turn-on state or a turn-off state based on the threshold voltage.

The selector layer 12 may include a diode, an OTS (Ovonic Threshold Switching) material such as a chalcogenide-based material, an MIEC (Mixed Ionic Electronic Conducting) material such as a metal-containing chalcogenide-based material, an MIT (Metal Insulator Transition) material such as NbO₂ or VO₂, a tunneling insulating layer having a relatively wide band gap such as SiO₂ or Al₂O₃, or the like. Alternatively, the selector layer 12 may include an insulating material doped with a dopant. Here, the insulating material may include a silicon-containing insulating material such as silicon oxide, silicon nitride, or silicon oxynitride, an insulating metal oxide, an insulating metal nitride, or a combination thereof. The dopant may serve to create trap sites that trap conductive carriers migrating within the insulating material or provide a path for the captured conductive carriers to migrate again. To form such a trap site, various elements capable of generating an energy level capable of accommodating the conductive carriers in the insulating material may be used as the dopant. For example, when the insulating material contains silicon, the dopant may include a metal having a different valence from silicon, such as gallium (Ga), boron (B), indium (In), phosphorus (P), arsenic (As), antimony (Sb), germanium (Ge), carbon (C), tungsten (W), or a combination thereof. Alternatively, when the insulating material contains a first metal, the dopant may include a second metal having a different valence from the first metal, silicon, or the like.

For example, the selector layer 12 may include silicon dioxide (SiO₂) doped with arsenic (As). When a voltage equal to or higher than the threshold voltage is applied to the selector layer 12 including the insulating material doped with the dopant, the conductive carriers may move through the trap sites, so the turn-on state in which current flows through the selector layer 12 may be implemented. On the other hand, when the voltage applied to the selector layer 12 is dropped below the threshold voltage, the conductive carriers may not move, so the turn-off state in which current does not flow through the selector layer 12 may be implemented.

The variable resistance layer 14 may be a part that functions to store data in the memory cell MC. To this end, the variable resistance layer 14 may have a variable resistance characteristic of switching between different resistance states according to an applied voltage. The variable resistance layer 14 may have a single layer structure or a multilayer structure including any of various materials used in RRAM, PRAM, FRAM, MRAM, etc. For example, the various materials include a metal oxide such as a transition metal oxide or a perovskite-based material, a phase change material such as a chalcogenide-based material, a ferroelectric material, a ferromagnetic material, and the like.

However, the layer structure of the memory cell MC is not limited to that shown in FIG. 1D. When the memory cell MC includes a variable resistance element, the stacking order of its layers can be changed, provided it includes the variable resistance layer 14 for data storage. Additionally, at least one of the stacked layers may be omitted. For example, one or more of the lower electrode layer 11, the selector layer 12, the intermediate electrode layer 13, and the upper electrode layer 15 may be omitted. Alternatively, the positions of the selector layer 12 and the variable resistance layers 14 may be reversed with each other. Alternatively, one or more layers (not shown) may be added to the memory cell MC to improve characteristics of the memory cell MC.

Referring back to FIGS. 1A to 1C, the plurality of word lines WL positioned at the same level in the vertical direction may be referred to as a word line layer, the plurality of bit lines BL positioned at the same level in the vertical direction may be referred to as a bit line layer, and the plurality of memory cells MC positioned at the same level in the vertical direction may be referred to as a memory cell layer. A single word line layer, a single bit line layer, and a single memory cell layer between them may be referred to as one deck. In this embodiment, one deck has been described, but embodiments of the present disclosure are not limited thereto. In another embodiment, a plurality of decks may be stacked in the vertical direction. As the number of stacked decks increases, it may be difficult to connect word lines and bit lines included in these decks to the driving circuits formed in the substrate, and an area of the semiconductor device including these decks may increase.

Hereinafter, an embodiment where 6 decks are stacked is proposed, and by appropriately connecting word lines and bit lines included in the 6 decks to a driving circuit formed in a substrate, random access to individual memory cells is possible while minimizing the increase in the area of a semiconductor device.

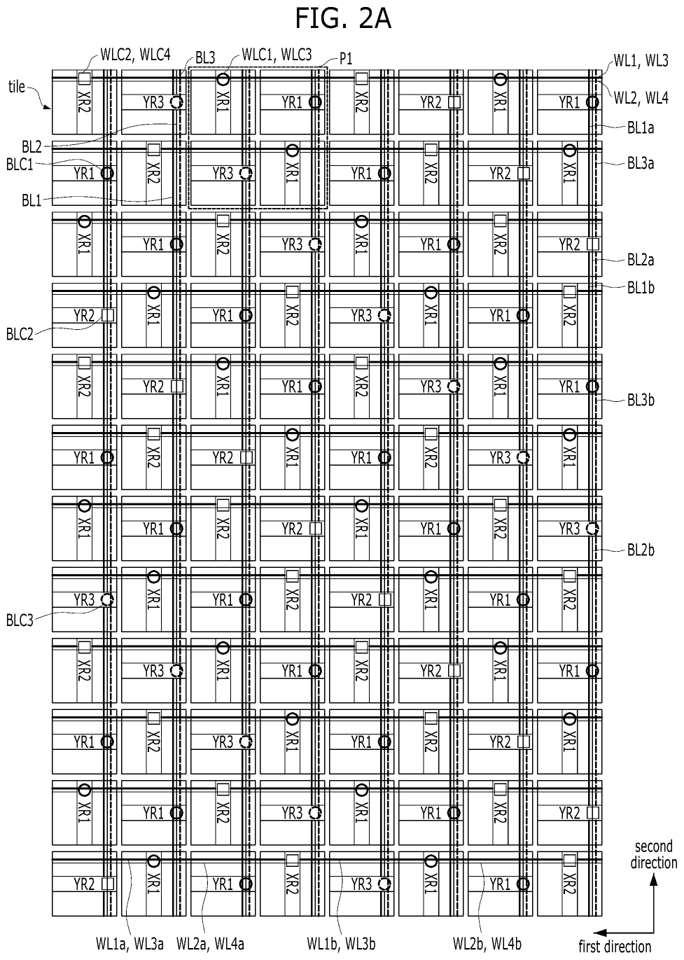

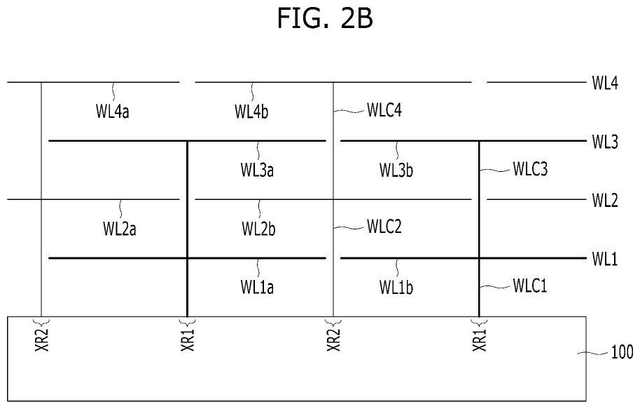

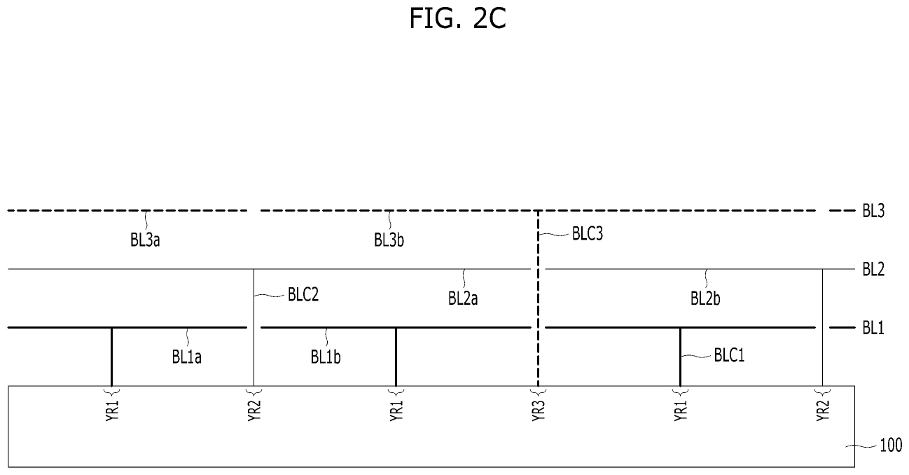

FIG. 2A is a plan view illustrating a semiconductor device according to another embodiment of the present disclosure. FIG. 2B is a cross-sectional view taken along a first direction of FIG. 2A, and FIG. 2C is a cross-sectional view taken along a second direction of FIG. 2A. For convenience of description, in the cross-sectional view of FIG. 2B, the focus is on word lines and word line contacts, while bit lines, bit line contacts, and memory cells are omitted. Also, for convenience of description, in the cross-sectional view of FIG. 2C, the focus is on the bit lines and the bit line contacts, while the word lines, the word line contacts, and the memory cells are omitted.

Referring to FIGS. 2A to 2C, the semiconductor device may include a substrate 100, first to fourth word lines WL1 to WL4 sequentially stacked over the substrate 100 and extending in the first direction, first to third bit lines BL1 to BL3 sequentially stacked over the substrate 100 and extending in the second direction crossing the first direction. In a vertical direction, the first bit line BL1 may be disposed between the first word line WL1 and the second word line WL2, the second bit line BL2 may be disposed between the second word line WL2 and the third word line WL3, and the third bit line BL3 may be disposed between the third word line WL3 and the fourth word line WL4.

The substrate 100 may include a semiconductor material such as silicon. In addition, a desired lower structure (not shown) may be formed in the substrate 100. For example, integrated circuits for driving the first to fourth word lines WL1 to WL4 and the first to third bit lines BL1 to BL3 may be formed in the substrate 100.

Referring to FIG. 2B, a plurality of first word lines WL1 may be arranged at the same level in the vertical direction to be parallel to each other in the second direction. Each of the plurality of first word lines WL1 may be divided into a plurality of segments by being cut at a predetermined area while positioned along a straight line that extends in the first direction. In particular, a first segment WL1a and a second segment WL1b of the first word line WL1 that are adjacent to each other in the first direction may be spaced apart from each other with second and fourth word line contacts WLC2 and WLC4 interposed therebetween in the first direction, not to be connected to the second and fourth word line contacts WLC2 and WLC4 described below. Since the arrangement of a plurality of third word lines WL3 and their segments in a plan view is substantially the same as the arrangement of the plurality of first word lines WL1 and their segments, a detailed description thereof will be omitted.

A plurality of second word lines WL2 may be arranged at the same level in the vertical direction to be parallel to each other in the second direction. In the second direction, the plurality of second word lines WL2 may overlap with the plurality of first word lines WL1 in a plan view and/or be aligned with the plurality of first word lines WL1, respectively.

In FIG. 2A, the first word line WL1 and the second word line WL2 are shown as being spaced apart by a predetermined interval in the second direction, but this is for clarifying the distinction between the first word line WL1 and the second word line WL2. Actually, the first word line WL1 and the second word line WL2 may overlap each other in the second direction in a plan view.

Each of the plurality of second word lines WL2 may be divided into a plurality of segments by being cut at a predetermined area while positioned along a straight line that extends in the first direction. Here, the cutting area of the second word line WL2 may be different from the cutting area of the first word line WL1. In particular, a first segment WL2a and a second segment WL2b of the second word line WL2 that are adjacent to each other in the first direction may be spaced apart from each other with first and third word line contacts WLC1 and WLC3 interposed therebetween in the first direction, not to be connected to the first and third word line contacts WLC1 and WLC3 described below. Since the arrangement of a plurality of fourth word lines WL4 and their segments in a plan view is substantially the same as the arrangement of the plurality of second word lines WL2 and their segments, a detailed description thereof will be omitted.

The first word line contact WLC1 may be disposed between the substrate 100 and the first word line WL1 in the vertical direction, and may serve to connect the first word line WL1 to a first word line driving circuit formed in the substrate 100. The first word line contact WLC1 may be connected to each segment of each of the plurality of first word lines WL1. The third word line contact WLC3 may be disposed between the third word line WL3 and the first word line WL1 in the vertical direction, and may serve to connect the third word line WL3 to the first word line WL1 corresponding thereto. Since the arrangement of a plurality of third word line contacts WLC3 in a plan view is substantially the same as the arrangement of a plurality of first word line contacts WLC1, a detailed description thereof will be omitted.

The second word line contact WLC2 may be disposed between the substrate 100 and the second word line WL2 in the vertical direction, and may serve to connect the second word line WL2 to a second word line driving circuit formed in the substrate 100. The second word line contact WLC2 may be connected to each segment of each of the plurality of second word lines WL2. The fourth word line contact WLC4 may be disposed between the second word line WL2 and the fourth word line WL4 in the vertical direction, and may serve to connect the fourth word line WL4 to the second word line WL2 corresponding thereto. Since the arrangement of a plurality of fourth word line contacts WLC4 in a plan view is substantially the same as the arrangement of the plurality of second word line contacts WLC2, a detailed description thereof will be omitted.

In a plan view, the first and third word line contacts WLC1 and WLC3 may be arranged at different positions from the second and fourth word line contacts WLC2 and WLC4. For example, as described below, they may be arranged in different tiles.

Referring to FIG. 2C, a plurality of first bit lines BL1 may be arranged at the same level in the vertical direction to be parallel to each other in the first direction. Each of the plurality of first bit lines BL1 may be divided into a plurality of segments by being cut at a predetermined area while positioned along a straight line that extends in the second direction. In particular, a first segment BL1a and a second segment BL1b of the first bit line BL1 that are adjacent to each other in the second direction may be spaced apart from each other with each of a second bit line contact BLC2 and a third bit line contact BLC3 that is interposed therebetween in the second direction, not to be connected to the second and third bit line contacts BLC2 and BLC3 described below.

A plurality of second bit lines BL2 may be arranged at the same level in the vertical direction to be parallel to each other in the first direction. In the first direction, the plurality of second bit lines BL2 may overlap with the plurality of first bit lines BL1 in a plan view and/or be aligned with the plurality of first bit lines BL1, respectively. Each of the plurality of second bit lines BL2 may be divided into a plurality of segments by being cut at a predetermined area while positioned along a straight line that extends in the second direction. Here, the cutting area of the second bit line BL2 may be different from the cutting area of the first bit line BL1. In particular, a first segment BL2a and a second segment BL2b of the second bit line BL2 that are adjacent to each other in the second direction may be spaced apart from each other with the third bit line contact BLC3 interposed therebetween in the second direction, not to be connected to the third bit line contacts BLC3. The second bit line BL2 may overlap a first bit line contact BLC1 in a plan view.

A plurality of third bit lines BL3 may be arranged at the same level in the vertical direction to be parallel to each other in the first direction. In the first direction, the plurality of third bit lines BL3 may overlap with the plurality of first bit lines BL1 and/or the plurality of second bit lines BL2 in a plan view, and/or be aligned with the plurality of first bit lines BL1 and/or the plurality of second bit lines BL2, respectively. Each of the plurality of third bit lines BL3 may be divided into a plurality of segments by being cut at a predetermined area while positioned along a straight line that extends in the second direction. Here, the cutting area of the third bit line BL3 may be different from the cutting areas of the first and second bit lines BL2. In particular, in a plan view, a first segment BL3a and a second segment BL3b of the third bit line BL3 that are adjacent to each other in the second direction may be spaced apart from each other with the second bit line contact BLC2 interposed therebetween.

In FIG. 2A, the first to third bit lines BL1 to BL3 are shown as being spaced apart by a predetermined interval in the first direction, but this is to clarify the distinction between the first to third bit lines BL1 to BL3. Actually, the first to third bit lines BL1 to BL3 may overlap each other in a plan view.

The first bit line contact BLC1 may be disposed between the substrate 100 and the first bit line BL1 in the vertical direction, and may serve to connect the first bit line BL1 to a first bit line driving circuit formed in the substrate 100. The first bit line contact BLC1 may be connected to each segment of each of the plurality of first bit lines BL1. The second bit line contact BLC2 may be disposed between the substrate 100 and the second bit line BL2 in the vertical direction, and may serve to connect the second bit line BL2 to a second bit line driving circuit formed in the substrate 100. The second bit line contact BLC2 may be connected to each segment of each of the plurality of second bit lines BL2. The third bit line contact BLC3 may be disposed between the substrate 100 and the third bit line BL3 in the vertical direction, and may serve to connect the third bit line BL3 to a third bit line driving circuit formed in the substrate 100. The third bit line contact BLC3 may be connected to each segment of each of the plurality of third bit lines BL3. In a plan view, the first to third bit line contacts BLC1 to BLC3 may be arranged at different positions from each other. For example, as described below, they may be arranged in different tiles.

Although not shown in these figures, a plurality of memory cells may be disposed between the first word line WL1 and the first bit line BL1, between the first bit line BL1 and the second word line WL2, between the second word line WL2 and the second bit line BL2, between the second bit line BL2 and the third word line WL3, between the third word line WL3 and the third bit line BL3, and between the third bit line BL3 and the fourth word line WL4, to overlap intersection regions of the word lines WL1 to WL4 and the bit lines BL1 to BL3.

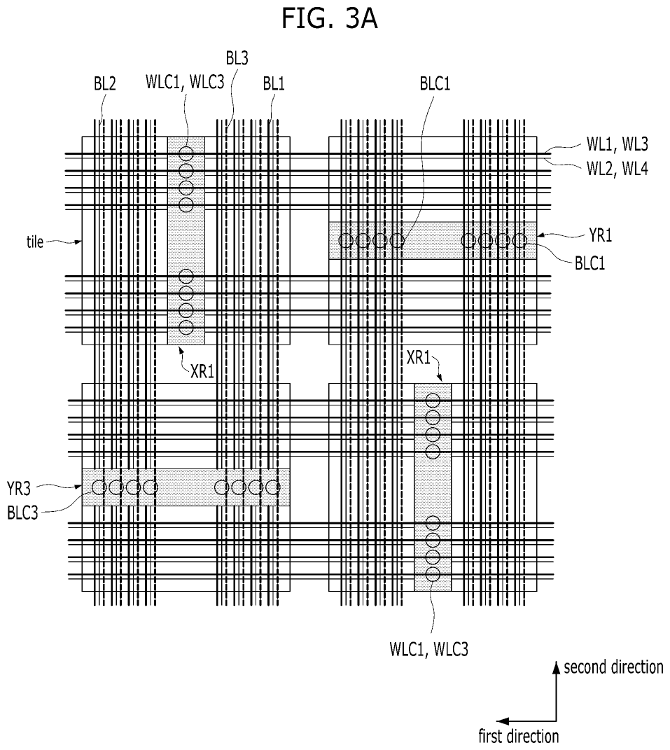

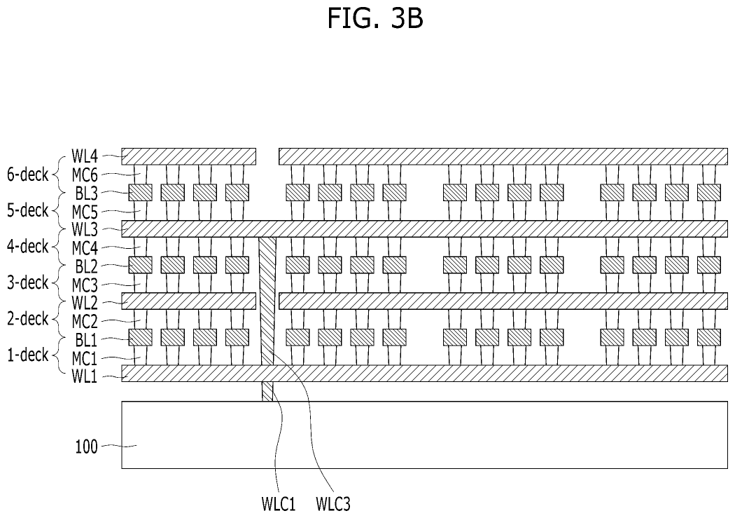

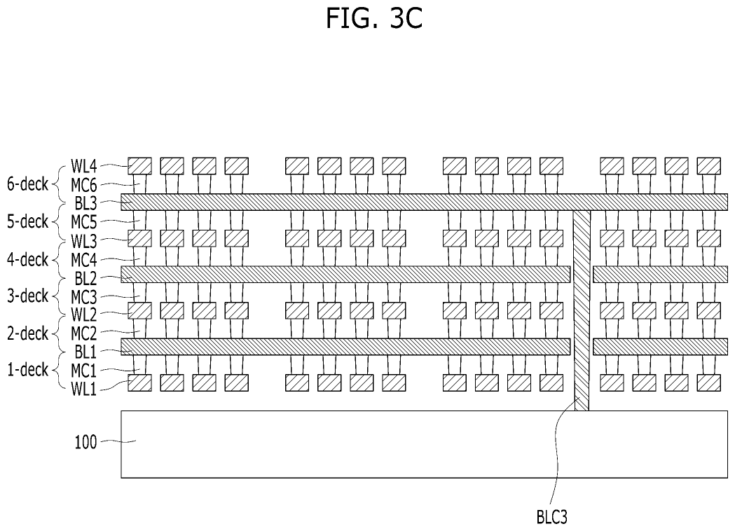

The first word lines WL1, the first bit lines BL1, and the memory cells disposed therebetween may form a first deck. The first bit lines BL1, the second word lines WL2, and the memory cells disposed therebetween may form a second deck. The second word lines WL2, the second bit lines BL2, and the memory cells disposed therebetween may form a third deck. The second bit lines BL2, the third word lines WL3, and the memory cells disposed therebetween may form a fourth deck. The third word lines WL3, the third bit lines BL3, and the memory cells disposed therebetween may form a fifth deck. The third bit lines BL3, the fourth word lines WL4, and the memory cells disposed therebetween may form a sixth deck. Therefore, the semiconductor device having the six decks is formed. This will be described in more detail with reference to FIGS. 3A to 3C.

Here, in a plan view, a unit area in which N*N memory cells per deck are arranged may be referred to as a tile, N being a natural number. In the tile, N first to fourth word lines WL1 to WL4 cross N first to third bit lines BL1 to BL3. A plurality of tiles may be arranged in a matrix form along the first and second directions. Although FIG. 2A illustrates a case in which 8 tiles are arranged in the first direction and 12 tiles are arranged in the second direction, embodiments are not limited thereto, and the number of tiles may be variously modified. In addition, FIG. 2A shows a case in which one first word line WL1, one second word line WL2, one third word line WL3, one fourth word line WL4, one first bit line BL1, one second bit line BL2, and one third bit line BL3 cross one tile, but this is for convenience of description. The number of each of the first to fourth word lines WL1 to WL4 and the number of each of the first to third bit lines BL1 to BL3 that cross one tile may be plural. For example, referring to FIGS. 3A to 3C, the number of each of the first to fourth word lines WL1 to WL4 crossing one tile is 8, and the number of each of the first to third bit lines BL1 to BL3 crossing one tile is 8.

In a plan view, a region in which N first word line contacts WLC1 are arranged to respectively connect the N first word lines WL1 crossing one tile to the substrate 100 will hereinafter be referred to as a first word line contact region XR1. N third word line contacts WLC3 may overlap the N first word line contacts WLC1, respectively, thereby being arranged in the first word line contact region XR1. Since the N first word lines WL1 are arranged in parallel to each other in the second direction, the first word line contact region XR1 may have a bar shape with a greater length in the second direction than in the first direction, or a shape similar thereto.

In addition, in a plan view, a region in which N second word line contacts WLC2 are arranged to respectively connect the N second word lines WL2 crossing one tile to the substrate 100 will hereinafter be referred to as a second word line contact region XR2. N fourth word line contacts WLC4 may overlap the N second word line contacts WLC2, respectively, thereby being arranged in the second word line contact region XR2. Since the N second word lines WL2 are arranged parallel to each other in the second direction, the second word line contact region XR2 may have a bar shape with a greater length in the second direction than in the first direction, or a shape similar thereto.

In addition, in a plan view, a region in which N first bit line contacts BLC1 are arranged to respectively connect the N first bit lines BL1 crossing one tile to the substrate 100 will hereinafter be referred to as a first bit line contact region YR1. Since the N first bit lines BL1 are arranged parallel to each other in the first direction, the first bit line contact region YR1 may have a bar shape with a greater length in the first direction than in the second direction, or a shape similar thereto.

In addition, in a plan view, a region in which N second bit line contacts BLC2 are arranged to respectively connect the N second bit lines BL2 crossing one tile to the substrate 100 will hereinafter be referred to as a second bit line contact region YR2. Since the N second bit lines BL2 are arranged parallel to each other in the first direction, the second bit line contact region YR2 may have a bar shape with a greater length in the first direction than in the second direction, or a shape similar thereto.

In addition, in a plan view, a region in which N third bit line contacts BLC3 are arranged to respectively connect the N third bit lines BL3 crossing one tile to the substrate 100 will hereinafter be referred to as a third bit line contact region YR3. Since the N third bit lines BL3 are arranged parallel to each other in the first direction, the first bit line contact region YR3 may have a bar shape with a greater length in the first direction than in the second direction, or a shape similar thereto.

In this embodiment, in one tile, one of the first word line contact region XR1, the second word line contact region XR2, the first bit line contact region YR1, the second bit line contact region YR2, and the third bit line contact region YR3 may be disposed. Accordingly, the first word line contact region XR1, the second word line contact region XR2, the first bit line contact region YR1, the second bit line contact region YR2, and the third bit line contact region YR3 are formed in different tiles, and they may be formed in different positions in a plan view.

Here, each of the first word line contact region XR1 and the second word line contact region XR2 may be located in a central region of a corresponding tile in the first direction. In this case, as illustrated in FIG. 3A, the same number of first to third bit lines BL1 to BL3 may be disposed on both sides of either the first word line contact region XR1 or the second word line contact region XR2 in the corresponding tile. Also, each of the first bit line contact region YR1, the second bit line contact region YR2, and the third bit line contact region YR3 may be located in a central region of a corresponding tile in the second direction. In this case, as illustrated in FIG. 3A, the same number of first to fourth word lines WL1 to WL4 may be disposed on both sides of either the first bit line contact region YR1, the second bit line contact regions YR2, or the third bit line contact region YR3 in the corresponding tile.

Further, in each of the first and second directions, any one of the first and second word line contact regions XR1 and XR2, and any one of the first to third bit line contact regions YR1, YR2, and YR3 may be alternately arranged. Furthermore, in the first direction, the first word line contact region XR1 and the second word line contact region XR2 may be alternately arranged. For example, when the first word line contact region XR1, any one of the first to third bit line contact regions YR1, YR2, and YR3, the second word line contact region XR2, and any one of the first to third bit line contact regions YR1, YR2, and YR3 are sequentially arranged in the first direction, they are referred to as a first unit, and a plurality of first units may be arranged in the first direction. Furthermore, in the second direction, the first bit line contact region YR1 may be alternately arranged with any one of the second and third bit line contact regions YR2 and YR3, and the second bit line contact region YR2 and the third bit line contact region YR3 may be alternately arranged. For example, when the first bit line contact region YR1, any one of the first and second word line contact regions XR1 and XR2, the second bit line contact region YR2, any one of the first and second word line contact regions XR1 and XR2, the first bit line contact region YR1, any one of the first and second word line contact regions XR1 and XR2, the third bit line contact region YR3, and any one of the first and second word line contact regions XR1 and XR2 are sequentially arranged in the second direction, they are referred to as a second unit, and a plurality of second units may be arranged in the second direction.

Meanwhile, FIG. 2A shows a case where the first word line contact region XR1 and the second word line contact region XR2 are alternately arranged in the second direction. That is, the arrangement of the first word line contact region XR1 and the second word line contact region XR2 in the second direction may be the same as the arrangement of the first word line contact region XR1 and the second word line contact region XR2 in the first direction. However, embodiments are not limited thereto. As long as the first word line contact region XR1 and the second word line contact region XR2 are alternately arranged in the first direction, the arrangement of the first word line contact region XR1 and the second word line contact region XR2 in the second direction may not be limited to the arrangement shown in FIG. 2A. For example, unlike FIG. 2A, the first word line contact region XR1 may be arranged in the leftmost column of tiles, while the second word line contact region XR2 may be positioned in the column immediately to the right of the leftmost column.

In addition, FIG. 2A shows a case where the first bit line contact region YR1 is alternately arranged with any one of the second and third bit line contact regions YR2 and YR3, and the second bit line contact region YR2 and the third bit line contact region YR3 are alternately arranged, in the first direction. That is, the arrangement of the first to third bit line contact regions YR1, YR2, and YR3 in the first direction may be the same as the arrangement of the first to third bit line contact regions YR1, YR2, and YR3 in the second direction. However, embodiments are not limited thereto. As long as the first bit line contact region YR1 is alternately arranged with any one of the second and third bit line contact regions YR2 and YR3, and the second bit line contact region YR2 and the third bit line contact region YR3 are alternately arranged in the second direction, the arrangement of the first to third bit line contact regions YR1, YR2, and YR3 in the first direction may not be limited to the arrangement shown in FIG. 2A. For example, unlike FIG. 2A, the first bit line contact region YR1 may be arranged in the uppermost row of tiles, the second bit line contact region YR2 may be arranged in the second row of tiles from the uppermost row, the first bit line contact region YR1 may be arranged in the third row of tiles from the uppermost row, and the third bit line contact region YR3 may be arranged in the fourth row of tiles from the uppermost row.

As shown in FIG. 2B, the first word line WL1 may extend in the first direction, and may overlap the first word line contact region XR1 and be cut over the second word line contact region XR2. Accordingly, when a length of one tile in the first direction is 1 k, a segment of the first word line WL1 may have a length of about 4 k. Since a segment of the third word line WL3 overlaps the segment of the first word line WL1, its length may be about 4 k, similar to that of the segment of the first word line WL1.

As shown in FIG. 2B, the second word line WL2 may extend in the first direction, and may overlap the second word line contact region XR2 and be cut over the first word line contact region XR1. Accordingly, when the length of one tile in the first direction is 1 k, a segment of the second word line WL2 may have a length of about 4 k. Since a segment of the fourth word line WL4 overlaps the segment of the second word line WL2, its length may be about 4 k, similar to that of the segment of the second word line WL2.

As shown in FIG. 2C, the first bit line BL1 may extend in the second direction, and may overlap the first bit line contact region YR1 and be cut over the second bit line contact region YR2 and the third bit line contact region YR3. Accordingly, when the length of one tile in the second direction is 1 k, a segment of the first bit line BL1 may have a length of about 4 k. The second bit line BL2 may extend in the second direction, and may overlap the first bit line contact region YR1 and the second bit line contact region YR2 and be cut over the third bit line contact region YR3. Accordingly, when the length of one tile in the second direction is 1 k, a segment of the second bit line BL2 may have a length of about 8 k.

As shown in FIG. 2C, the third bit line BL3 may extend in the second direction, and may overlap the first bit line contact region YR1 and the third bit line contact region YR3 and be cut over the second bit line contact region YR2. Accordingly, when the length of one tile in the second direction is 1 k, a segment of the third bit line BL3 may have a length of about 8 k.

That is, while the segments of the first to fourth word lines WL1 to WL4 and the first bit line BL1 may all have the same length, the segments of the second and third bit lines BL2 and BL3 may have a length twice as long as that of the first to fourth word lines WL1 to WL4 and the first bit line BL1.

In the semiconductor device described above, since each segment of each of the first to fourth word lines WL1 to WL4 and each segment of each of the first to third bit lines BL1 to BL3 can be activated individually, individual access to memory cells respectively disposed in intersection regions thereof may be possible.

For example, referring to FIG. 2A, in order to access a memory cell that is disposed between the right segment of the segments of the first word line WL1 crossing the uppermost and leftmost tile and the segment of the first bit line BL1 crossing the right segment and overlaps an intersection region thereof, the segment of the first word line WL1 connected to the first word line contact WLC1 existing in the first word line contact region XR1 of the third tile from the leftmost may be activated, and the segment of the first bit line BL1 connected to the first bit line contact BLC1 existing in the first bit line contact region YR1 of the second tile from the uppermost may be activated. In addition, an area increase of the semiconductor device may be minimized by appropriately arranging the first and second word line contact regions XR1 and XR2, and the first to third bit line contact regions YR1, YR2, and YR3.

FIG. 3A is a plan view illustrating an enlarged portion P1 of FIG. 2A in more detail. FIG. 3B is a cross-sectional view taken along a first direction of FIG. 3A, and FIG. 3C is a cross-sectional view taken along a second direction of FIG. 3A. Components omitted in FIGS. 2A to 2C will be described in more detail with reference to these figures. A detailed description of the components previously with reference to FIGS. 2A to 2C will be omitted for illustrative convenience.

Referring to FIGS. 3A to 3C, the plurality of first word lines WL1, the plurality of first bit lines BL1, the plurality of second word lines WL2, the plurality of second bit lines BL2, the plurality of third word lines WL3, the plurality of third bit lines BL3, and the plurality of fourth word lines WL4 may be sequentially stacked over the substrate 100 in the vertical direction. A plurality of first memory cells MC1 may be disposed at the intersection regions of the first word lines WL1 and the first bit lines BL1, overlapping the intersection regions, a plurality of second memory cells MC2 may be disposed at the intersection regions of the first bit lines BL1 and the second word lines WL2, overlapping the intersection regions, a plurality of third memory cells MC3 may be disposed at the intersection regions of the second word lines WL2 and the second bit lines BL2, overlapping the intersection regions, a plurality of fourth memory cells MC4 may be disposed at the intersection regions of the second bit lines BL2 and the third word lines WL3, overlapping the intersection regions, a plurality of fifth memory cells MC5 may be disposed at the intersection regions of the third word lines WL3 and the third bit lines BL3, overlapping the intersection regions, and a plurality of sixth memory cells MC6 may be disposed at the intersection regions of the third bit lines BL3 and the fourth word lines WL4, overlapping the intersection regions. The first word lines WL1, the first bit lines BL1, and the first memory cells MC1 disposed therebetween may form a first deck, the first bit lines BL1, the second word lines WL2, and the second memory cells MC2 disposed therebetween may form a second deck, the second word lines WL2, the second bit lines BL2, and the third memory cells MC3 disposed therebetween may form a third deck, the second bit lines BL2, the third word lines WL3, and the fourth memory cells MC4 disposed therebetween may form a fourth deck, the third word lines WL3, the third bit lines BL3, and the fifth memory cells MC5 disposed therebetween may form a fifth deck, and the third bit lines BL3, the fourth word lines WL4, and the sixth memory cells MC6 disposed therebetween may form a sixth deck.

FIG. 3A illustrates an embodiment in which eight first to fourth word lines WL1 to WL4 and eight first to third bit lines BL1 to BL3 are disposed per tile. Here, the first word line contact region XR1 may be located in a central region of a tile in the first direction, so that, among the eight first to third bit lines BL1 to BL3, a first set of four first to third bit lines BL1 to BL3 and a second set of four first to third bit lines BL1 to BL3 may be provided on both sides of the first word line contact region XR1 in the first direction. Similarly, as shown in FIG. 2A, the second word line contact region XR2 may also be located in a central region of a tile in the first direction. The first bit line contact region YR1 may be located in a central region of a tile in the second direction, so that, among the eight first to fourth word lines WL1 to WL4, a first set of four first to fourth word lines WL1 to WL4 and a second set of four first to fourth word lines WL1 to WL4 may be provided on both sides of the first bit line contact region YR1 in the second direction. The third bit line contact region YR3 may be located in a central region of a tile in the second direction, so that, among the eight first to fourth word lines WL1 to WL4, a first set of four first to fourth word lines WL1 to WL4 and a second set of four first to fourth word lines WL1 to WL4 may be provided on both sides of the third bit line contact region YR3 in the second direction. Similarly, as shown in FIG. 2A, the second bit line contact region YR2 may also be located in a central region of a tile in the second direction.

Referring to FIG. 3B, the eight first word line contacts WLC1 may be disposed in the first word line contact region XR1, and the eight first word lines WL1 may be connected to a first word line driving circuit formed in the substrate 100 through the eight first word line contacts WLC1 respectively connected thereto. The eight third word line contacts WLC3 may be disposed in the first word line contact region XR1, and the eight third word lines WL3 may be connected to the eight first word lines WL1, respectively, through the eight third word line contacts WLC3 respectively connected thereto. Accordingly, the first word line WL1 and the third word line WL3 may be commonly connected to the first word line driving circuit formed in the substrate 100.

Similarly, although not shown, the eight second word line contacts WLC2 may be disposed in the second word line contact region XR2, and the eight second word lines WL2 may be connected to a second word line driving circuit formed in the substrate 100 through the eight second word line contacts WLC2 respectively connected thereto. The eight fourth word line contacts WLC4 may be disposed in the second word line contact region XR2, and the eight fourth word lines WL4 may be connected to the eight second word lines WL2, respectively, through the eight fourth word line contacts WLC4 respectively connected thereto. Accordingly, the second word line WL2 and the fourth word line WL4 may be commonly connected to the second word line driving circuit formed in the substrate 100.

In addition, the eight first bit line contacts BLC1 may be disposed in the first bit line contact region YR1, and the eight first bit lines BL1 may be connected to a first bit line driving circuit formed in the substrate 100 through the eight first bit line contacts BLC1 respectively connected thereto. The eight third bit line contacts BLC3 may be disposed in the third bit line contact region YR3, and the eight third bit lines BL3 may be connected to a third bit line driving circuit formed in the substrate 100 through the eight third bit line contacts BLC3 respectively connected thereto. Similarly, although not shown, the eight second bit line contacts BLC2 may be disposed in the second bit line contact region YR2, and the eight second bit lines BL2 may be connected to a second bit line driving circuit formed in the substrate 100 through the eight second bit line contacts BLC2 respectively connected thereto. That is, the first to third bit lines BL1 to BL3 may be driven independently of each other.

As described above, when the first and third word lines WL1 and WL3 are driven in common, the second and fourth word lines WL2 and WL4 are driven in common while being driven independently of the first and third word lines WL1 and WL3. The first to third bit lines BL1 to BL3 are driven independently of each other.

A method of selecting one of the first to sixth memory cells MC1 to MC6 may be as follows. When the first memory cell MC1 is selected, a driving voltage may be applied to the first and third word lines WL1 and WL3 and the first bit line BL1 to activate them. When the second memory cell MC2 is selected, a driving voltage may be applied to the second and fourth word lines WL2 and WL4 and the first bit line BL1 to activate them. When the third memory cell MC3 is selected, a driving voltage may be applied to the second and fourth word lines WL2 and WL4 and the second bit line BL2 to activate them. When the fourth memory cell MC4 is selected, a driving voltage may be applied to the first and third word lines WL1 and WL3 and the second bit line BL2 to activate them. When the fifth memory cell MC5 is selected, a driving voltage may be applied to the first and third word lines WL1 and WL3 and the third bit line BL3 to activate them. When the sixth memory cell MC6 is selected, a driving voltage may be applied to the second and fourth word lines WL2 and WL4 and the third bit line BL3 to activate them.

According to the above embodiments of the present disclosure, while stacking six decks, the increase in the area of the semiconductor device can be kept to a minimum.

Although various embodiments have been described for illustrative purposes, it will be apparent to those skilled in the art that various changes and modifications may be made without departing from the spirit and scope of the present teachings as defined in the following claims.

What is claimed is:

1. A semiconductor device comprising:
a substrate;
first to fourth word lines extending in a first direction that is parallel to a top surface of the substrate, and sequentially stacked over the substrate in a vertical direction perpendicular to the top surface of the substrate;
first to third bit lines extending in a second direction that is parallel to the top surface of the substrate and crosses the first direction, and disposed between the first word line and the second word line, between the second word line and the third word line, and between the third word line and the fourth word line, respectively, in the vertical direction;
first to sixth memory cells disposed in an intersection region between the first word line and the first bit line, an intersection region between the first bit line and the second word line, an intersection region between the second word line and the second bit line, an intersection region between the second bit line and the third word line, an intersection region between the third word line and the third bit line, and an intersection region between the third bit line and the fourth word line, respectively;
first and second word line contacts respectively connecting the first and second word lines to the substrate, and third and fourth word line contacts respectively connecting the third and fourth word lines to the first and second word lines; and
first to third bit line contacts respectively connecting the first to third bit lines to the substrate,
wherein, in a plan view, a first word line contact region where the first and third word line contacts are disposed, a second word line contact region where the second and fourth word line contacts are disposed, a first bit line contact region where the first bit line contact is disposed, a second bit line contact region where the second bit line contact is disposed, and a third bit line contact region where the third bit line contact is disposed are located at different positions.

2. The semiconductor device according to claim 1, wherein the first and third word lines are commonly activated,
the second and fourth word lines are commonly activated, but they are activated independently of the first and third word lines, and
the first to third bit lines are independently activated from each other.

3. The semiconductor device according to claim 1, wherein the first memory cell is selected by the first and third word lines and the first bit line,
the second memory cell is selected by the second and fourth word lines and the first bit line,
the third memory cell is selected by the second and fourth word lines and the second bit line,
the fourth memory cell is selected by the first and third word lines and the second bit line,
the fifth memory cell is selected by the first and third word lines and the third bit line, and
the sixth memory cell is selected by the second and fourth word lines and the third bit line.

4. The semiconductor device according to claim 1, wherein, in the first direction, each of the first and third word lines is divided into a plurality of segments, and the plurality of segments of each of the first and third word lines are spaced apart from each other with the second and fourth word line contacts interposed therebetween, and
in the first direction, each of the second and fourth word lines is divided into a plurality of segments, and the plurality of segments of each of the second and fourth word lines are spaced apart from each other with the first and third word line contacts interposed therebetween in a plan view.

5. The semiconductor device according to claim 1, wherein, in the second direction, the first bit line is divided into a plurality of segments, and the plurality of segments of the first bit line are spaced apart from each other with the second bit line contact and the third bit line contact interposed therebetween,
in the second direction, the second bit line is divided into a plurality of segments, and the plurality of segments of the second bit line are spaced apart from each other with the third bit line contact interposed therebetween, and
in the second direction, the third bit line is divided into a plurality of segments, and the plurality of segments of the third bit line are spaced apart from each other with respect to the second bit line contact interposed therebetween in a plan view.

6. The semiconductor device according to claim 1, wherein the substrate includes a plurality of tiles arranged in the first direction and the second direction, and
the first word line contact region, the second word line contact region, the first bit line contact region, the second bit line contact region, and the third bit line contact region are located in different tiles.

7. The semiconductor device according to claim 6, wherein, in each of the first direction and the second direction, any one of the first and second word line contact regions and any one of the first to third bit line contact regions are alternately arranged.

8. The semiconductor device according to claim 7, wherein, in the first direction, the first word line contact region and the second word line contact region are alternately arranged.

9. The semiconductor device according to claim 7, wherein, in the second direction, the first bit line contact region is alternately arranged with any one of the second and third bit line contact regions, and the second bit line contact region and the third bit line contact region are alternately arranged.

10. The semiconductor device according to claim 8, wherein, in the first direction, each of the first and third word lines is divided into a plurality of segments, and the plurality of segments of each of the first and third word lines are spaced apart from each other with the second and fourth word line contacts interposed therebetween,
in the first direction, each of the second and fourth word lines is divided into a plurality of segments, and the plurality of segments of each of the second and fourth word lines are spaced apart from each other with the first and third word line contacts interposed therebetween,
in a plan view, the second and fourth word line contacts overlap each other and the first and third word line contacts overlap each other, and
a length of each segment of each of the first and third word lines is substantially the same as a length of each segment of each of the second and fourth word lines.

11. The semiconductor device according to claim 9, wherein, in the second direction, the first bit line is divided into a plurality of segments, and the plurality of segments of the first bit line are spaced apart from each other with the second bit line contact and the third bit line contact that are interposed therebetween,
in the second direction, the second bit line is divided into a plurality of segments, and the plurality of segments of the second bit line are spaced apart from each other with the third bit line contact interposed therebetween,
in the second direction, the third bit line is divided into a plurality of segments, and the plurality of segments of the third bit line are spaced apart from each other with respect to the second bit line contact interposed therebetween in a plan view, and
a length of each segment of the second bit line and a length of each segment of the third bit line are twice a length of each segment of the first bit line.

12. The semiconductor device according to claim 6, wherein each of the first and second word line contact regions has a shape in which a length in the second direction is greater than a length in the first direction in a corresponding tile, and is located at a central region of the corresponding tile in the first direction.

13. The semiconductor device according to claim 6, wherein each of the first to third bit line contact regions has a shape in which a length in the first direction is greater than a length in the second direction in a corresponding tile, and is located at a central region of the corresponding tile in the second direction.

14. A semiconductor device comprising:
a substrate including a plurality of tiles arranged in a first direction and a second direction, the first and the second direction being parallel to a top surface of the substrate and crossing each other, the substrate further including first and second word line contact regions and first to third bit line contact regions that are arranged in different tiles;
first to fourth word lines extending in the first direction and sequentially stacked over the substrate in a vertical direction perpendicular to the top surface of the substrate;
first, second, and third bit lines extending in the second direction, and disposed between the first word line and the second word line, between the second word line and the third word line, and the third word line and the fourth word line, respectively, in the vertical direction;
first to sixth memory cells disposed in an intersection region between the first word line and the first bit line, an intersection region between the first bit line and the second word line, an intersection region between the second word line and the second bit line, an intersection region between the second bit line and the third word line, an intersection region between the third word line and the third bit line, and an intersection region between the third bit line and the fourth word line, respectively;
first and third word line contacts connecting the first and third word lines to the first word line contact region of the substrate;
second and fourth word line contacts connecting the second and fourth word lines to the second word line contact region of the substrate; and
first to third bit line contacts respectively connecting the first to third bit lines to the first to third bit line contact regions of the substrate.

15. The semiconductor device according to claim 14, wherein, in each of the first direction and the second direction, any one of the first and second word line contact regions and any one of the first to third bit line contact regions are alternately arranged,
in the first direction, the first word line contact region and the second word line contact region are alternately arranged, and
in the second direction, the first bit line contact region is alternately arranged with any one of the second and third bit line contact regions, and the second bit line contact region and the third bit line contact region are alternately arranged.

16. The semiconductor device according to claim 15, wherein, in the first direction, each of the first and third word lines is divided into a plurality of segments, and the plurality of segments of each of the first and third word lines are spaced apart from each other with the second and fourth word line contacts interposed therebetween, and
in the first direction, each of the second and fourth word lines is divided into a plurality of segments, and the plurality of segments of each of the second and fourth word lines are spaced apart from each other with the first and third word line contacts interposed therebetween in a plan view.

17. The semiconductor device according to claim 16, wherein a length of each segment of each of the first and third word lines is substantially the same as a length of each segment of each of the second and fourth word lines.

18. The semiconductor device according to claim 15, wherein, in the second direction, the first bit line is divided into a plurality of segments, and the plurality of segments of the first bit line are spaced apart from each other with the second bit line contact and the third bit line contact interposed therebetween,
in the second direction, the second bit line is divided into a plurality of segments, and the plurality of segments of the second bit line are spaced apart from each other with the third bit line contact interposed therebetween, and
in the second direction, the third bit line is divided into a plurality of segments, and the plurality of segments of the third bit line are spaced apart from each other with respect to the second bit line contact interposed therebetween in a plan view.

19. The semiconductor device according to claim 18, wherein a length of each segment of the second bit line and a length of each segment of the third bit line are twice a length of each segment of the first bit line.

20. The semiconductor device according to claim 14, wherein the first memory cell is selected by the first and third word lines and the first bit line,
the second memory cell is selected by the second and fourth word lines and the first bit line,
the third memory cell is selected by the second and fourth word lines and the second bit line,
the fourth memory cell is selected by the first and third word lines and the second bit line,
the fifth memory cell is selected by the first and third word lines and the third bit line, and
the sixth memory cell is selected by the second and fourth word lines and the third bit line.
